(19) United States
(12) Patent Application Publication
(10) Pub. No.: US 2022/0256714 A1
(43) Pub. Date: Aug. 11, 2022

(54) METHOD FOR PRODUCING A PRE-TINNING ARRANGEMENT AND PRE-TINNING ARRANGEMENT OF THIS TYPE

(71) Applicant: FEW Fahrzeugelektrik Werk GmbH & Co. KG, Zwenkau (DE)

(72) Inventors: Hendrik Niemann, Taucha (DE); David Roger, Leipzig (DE)

(21) Appl. No.: 17/581,500

(22) Filed: Jan. 21, 2022

(30) Foreign Application Priority Data
Feb. 5, 2021 (DE) 102021102744.6
Feb. 12, 2021 (DE) 102021103360.8

(51) Int. Cl. H05K 3/34; B23K 1/20; B23K 35/26; C22C 13/02

(52) U.S. Cl. CPC H05K 3/3478; C22C 13/02; B23K 35/262; B23K 1/20

(57) ABSTRACT

The invention relates to a method for producing a pre-tinning arrangement on a conductive surface, wherein, for a temporally and/or spatially subsequent soldering process, a soldering tin preform or a soldering tin round blank having a predefined three-dimensional shape is connected to the conductive surface in a captive and transportation-stable manner. For this purpose, the soldering tin preform or soldering tin round blank is fixed onto the conductive surface by means of a tacking solder, wherein the melting temperature of the tacking solder is below the melting temperature of the soldering tin preform or soldering tin round blank.

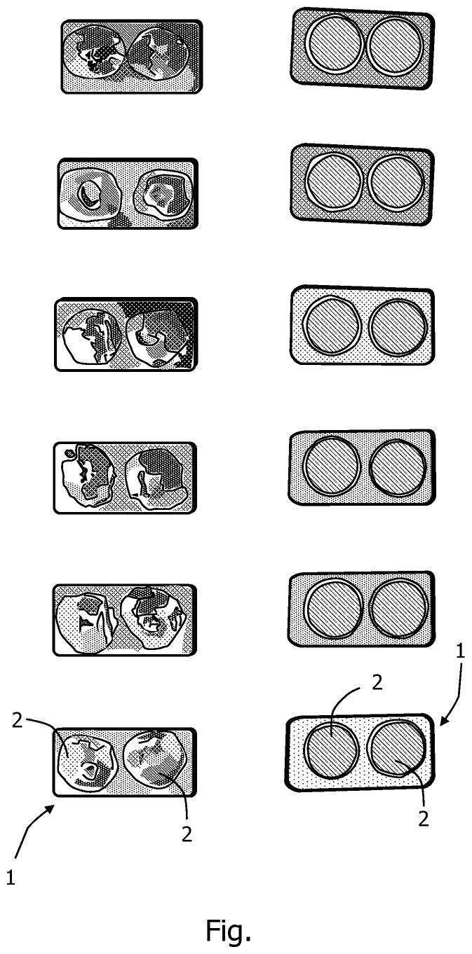

The invention relates to a method for producing a pre-tinning arrangement on a conductive surface, wherein, for a temporally and/or spatially subsequent soldering process, a soldering tin preform or a soldering tin round blank having a predefined three-dimensional shape is connected to the conductive surface in a captive and transportation-stable manner, according to claim 1, as well as to a pre-tinning arrangement applied onto a conductive surface according to claim 9.

From EP 2 760 613 B1, a layer composite of an electronic substrate and a layer arrangement, comprising a reaction solder, is already known. For bonding electronic or electrical components, for example on a carrier substrate, by means of a connecting layer, solder compounds usually are employed.

Soft solders are usually employed here, which include alloys of tin and silver or of tin and silver and copper. At temperatures close to the melting temperature, such connecting layers exhibit fading electrical and mechanical properties, which may result in failure of corresponding assemblies.

Lead-containing solder compounds can be employed at higher operation temperatures than soft solder compounds, but are strictly limited in their technical applications by legal regulations for reasons of environmental protection.

Alternatively, the use of lead-free hard solders is recommended for the use at increased or higher temperatures, in particular above 200° C. When hard solder is employed for forming a connecting layer, however, only few electrical or electronic components, which are able to withstand the respective high temperatures when the hard solders are melting, are possible as joining partners.

In this respect, the so-called low-temperature connecting technology is often referred to, in which silver-containing sinter compounds may be produced at temperatures that are already significantly lower than the melting temperature. Here, it is known to use a paste instead of a solder, which paste contains chemically stabilized silver particles and/or silver compounds.

EP 2 760 613 B1 is aimed at a layer composite comprising at least one electronic substrate and a layer arrangement of at least one first layer of a first metal and/or a first metal alloy, and of a second layer of a second metal and/or a second metal alloy adjacent to said first layer, wherein the melting temperatures of the first and the second layers are different, and wherein, after a temperature treatment of the layer arrangement, a region having at least one intermetallic phase is formed between the first layer and the second layer.

Specifically, an AgX alloy, CuX alloy or NiX alloy is referred to, which has a melting temperature which is greater than the melting temperature of a base solder.

In a corresponding method for forming a layer composite of a base solder and a reaction solder, an interdiffusion of the metals and/or metal alloy in the first and/or the second layer takes place as a result of a temperature treatment of the layer arrangement or the raw layer composite. As a result, an intermetallic phase is generated between the first and the second layer. The base solder is selected from the group of Sn, Cu, SnAg, SnAu, SbBi, SnNi, SnZn, CuIn, CuAg, AgBi or ZNAl, respectively InGa.

Due to the solution approach according to EP 2 760 613 B1, compounds are created, which withstand the application temperatures close to the melting temperature of the employed solder.

WO 2013/142335 A1 and U.S. Pat. No. 9,801,285 B2 disclose a solder paste, which is applied onto an electronic substrate so as to create a solder paste deposit. Thereafter, a low-temperature preform is arranged within the solder paste deposit. Subsequently the arrangement formed in such a manner is subjected to a reflow soldering process.

In this case, a quasi new alloy having a lower melting point is generated. By way of example, SAC305 is employed as the solder paste. The preform consists of a tin/bismuth alloy.

In a further embodiment, it is explained to apply a low-temperature solder paste, for example Sn42Bi58 onto a circuit board so as to obtain corresponding deposits. Thereafter, preforms of a higher melting temperature, for example SAC305 preforms are applied.

The thus resulting combination is likewise subjected to a reflow temperature, whereby the high-temperature preform mixes with the paste, with the result of the melting temperature of the occurring mixture being reduced.

The teaching of EP 2 908 612 B1 points in a similar direction for forming a mixed solder.

Known connectors, which can be laminated into vehicle panes, for example, may consist of (flat) conductors made of a copper tape of a thickness of about 0.1 mm.

Pre-tinning of these flat conductors usually is performed at the connections by means of tin preforms or tin round blanks.

According to the state of the art, the preforms are soldered onto the copper tape inductively or thermally by means of a soldering iron. In this case, the soldering tin liquifies and loses its shape.

As a consequence of the surface and interface tensions, drop-like geometries having extremely uneven surfaces are created in this case.

As a result of extensive trials and investigations, it has been found that such drop-like, uneven surface geometries are significantly disadvantageous for the subsequent, actual soldering process.

In particular in the subsequent soldering process by means of inductive soldering methods, exactly reproducible layer thicknesses are required with respect to the preforms or round blanks. In case of multiple round blanks, the distances between the round blanks and the height dimensions are likewise relevant for the soldering success.

Height differences of the round blanks in themselves or between adjacent round blanks in a range of about 10 μm are in this case desirable.

This uniformity of the preforms or round blanks exhibits the advantage of uniformly transferring heat, which results is a more uniform heating of the substrate and avoids thermal tensions caused by expansion from occurring.

From the aforementioned, it is therefore a task of the invention to propose a further developed method for producing a pre-tinning arrangement on a conductive surface while using soldering tin preforms or soldering tin round blanks, which allows the preforms or round blanks to be fixed on the conductive surface in a captive and transportation-stable manner such that a modification of the three-dimensional shape of the preforms or round blanks is excluded.

The product premanufactured in this respect should then be subjected with the obtained geometric stability by the final user to a usual soldering process with the optimum quality and long-term stability as a result of soldering. In fixing the soldering preforms or round blanks, the formation of intermetallic phases should be prevented.

As far as the method is concerned, the solution of the invention is performed by a teaching according to claim 1, as well as with respect to the arrangement, by a solution according to the feature combination of claim 9.

Consequently, a method for producing a pre-tinning arrangement on a conductive surface, for example a copper tape, is taken as a basis, wherein, for a temporally and/or spatially subsequent soldering process, at least one or more soldering tin preforms or soldering tin round blanks having a predefined three-dimensional shape are connected to the conductive surface in a captive and transportation-stable manner.

In contrast to previous measures of the state of the art, in which the soldering tin preforms or soldering tin round blanks are connected to the conductive surface by melting them, the soldering tin preforms or soldering tin round blanks are fixed according to the invention on the conductive surface by tacking solder, with the melting temperature of the tacking solder being below the melting temperature of the corresponding soldering tin preform or soldering tin round blank such that a shape modification of its three-dimensional shape is largely suppressed or completely eliminated during the tacking soldering process.

For this purpose, the melting temperature of the tacking solder, for example, is in the range between 35° C. and about 90° C. below the melting temperature of the soldering tin preform alloy or the alloy of the soldering tin round blank.

For example, Sn42Bi47Ag1 or an alloy containing indium or bismuth is employed as the tacking solder.

For example, SAC305, Sn62Pb36Ag2 or Sn98Ag2 is employed as the alloy material for the soldering tin preforms or soldering tin round blanks.

The selection of the tacking solder takes place under the aspect of avoiding the formation of undesired intermetallic compounds during the tacking soldering step. In this respect, tacking soldering is thus performed at a minimum energy input amount. In this respect, it must merely be secured that the actual soldering preforms or soldering round blanks remain connected to the corresponding conductive surface captively until the soldering process at the final customer's place.

The respective soldering tin preform may consist of single or multiple round blanks, with the height or the layer thickness of their three-dimensional shape being maintained and the layer thickness or height differences from one round blank to the next being avoided after the tacking soldering step.

Preferably, the tacking solder may be applied in paste form onto the conductive surface or onto the rear side of the soldering tin preform or corresponding round blanks.

The conductive surface may be formed by a copper film or a copper tape.

The pre-tinning arrangement according to the invention is applied onto a conductive surface and is based on one or more three-dimensionally shaped soldering tin preforms or soldering tin round blanks.

For connecting the soldering tin preforms or soldering tin round blanks to the conductive surface, the latter has a tacking solder layer.

The melting temperature of the tacking solder layer is below that of the soldering tin preforms or soldering tin round blanks.

Depending on the selected alloy, the melting temperature of the soldering tin preforms is in the range between 100° C. and 170° C. up to 250° C.

The melting temperature of a preferably employed tacking solder, e.g. Sn42Bi47Ag1, is at about 139° C.

It is obvious that at this temperature difference between the melting points when the tacking solder is fixed, a melting or through-melt of the soldering tin preforms is avoided but a secure adhesion can be achieved nevertheless.

The proposed tacking soldering process is basically performed such that the employed soldering round blanks or soldering preforms remain dimensionally stable. This results in the further advantage that at least the major part of the corresponding soldering round blank remains unchanged in its alloy.

Disadvantages occurring during a first melting of the preform or round blank material and changing the melting properties thus are missing so that all of the desired properties of the soldering tin preform alloy are maintained until its active use in a soldering process at the customer's place.

The invention will be explained in more detail hereinafter on the basis of an exemplary embodiment and a FIGURE.

In this case, the FIGURE shows a photo-realistic representation of a comparison of a soldering preform applied onto a partially covered copper tape and having double round blanks.

At the right-hand side, an arrangement of preforms 1 having round blanks 2 with quasi sharp edges can be recognized in the FIGURE, which round blanks had been fixed according to the method of the invention onto a conductive copper tape not recognizable in the FIGURE via a tacking solder. In comparison thereto, the formation of preforms 1 according to the state of the art can be recognized at the left-hand side.

The round blanks are completely melted and form a drop structure having an irregular surface and irregular thickness or height dimensions.

By way of example, alloys such as SAC305, Sn62Pb36Ag2 or Sn98Ag2 are employed for the preforms.

The melting point of SAC305 is at 217° C., the melting point of Sn62Pb36Ag2 is at about 179° C., and the melting point of Sn98Ag2 is in the range between 221° C. and 226° C.

The printing paste employed as the tacking solder consists of an alloy of Sn42Bi47Ag1 and exhibits a significantly lower melting point of about 139° C.

It is within the spirit of the invention to employ also similar alloys as the tacking solder, for example alloys having an indium component. The lower melting point of the tacking solder with respect to the meting point of the preforms or round blanks is decisive here.

1. A method for producing a pre-tinning arrangement on a conductive surface, wherein, for a temporally and/or spatially subsequent soldering process, a soldering tin preform or a soldering tin round blank (1; 2) having a predefined three-dimensional shape is connected to the conductive surface in a captive and transportation-stable manner,
characterized in that
the soldering tin preform or soldering tin round blank (1; 2) is fixed onto the conductive surface by means of a tacking solder, wherein the melting temperature of the tacking solder is below the melting temperature of the soldering tin preform or soldering tin round blank (1; 2) such that a shape modification of its three-dimensional shape is largely suppressed or completely eliminated during the tacking soldering process.

2. The method according to claim 1,
characterized in that
the melting temperature of the tacking solder is in the range between 35° C. and 90° C. below the melting temperature of the soldering tin preform or the soldering tin round blank (1; 2).

3. The method according to claim 1,
characterized in that
Sn42Bi47Ag1 or an alloy containing indium or bismuth is employed as the tacking solder.

4. The method according to claim 1,
characterized in that
SAC305, Sn62Pb36Ag2 or Sn98Ag2 is employed as the alloy for the soldering tin preforms or soldering tin round blanks.

5. The method according to claim 1,
characterized in that
the selection of the tacking solder takes place under the aspect of avoiding the formation of undesired intermetallic compounds during the tacking soldering step.

6. The method according to claim 1,
characterized in that
the respective soldering tin preform consists of single or multiple round blanks, with the height or the layer thickness of their three-dimensional shape being maintained and the layer thickness or height differences from one round blank to the next being avoided after the tacking soldering step.

7. The method according to claim 1,
characterized in that
the tacking solder is applied onto the conductive surface in paste form.

8. The method according to claim 1,
characterized in that
the conductive surface is formed by a copper film or a copper tape.

9. A pre-tinning arrangement, applied onto a conductive surface, on the basis of one or more three-dimensionally shaped soldering tin preforms or soldering tin round blanks (1; 2),
characterized in that
for connecting the soldering tin preforms or soldering tin round blanks (1; 2) to the conductive surface, the conductive surface has a tacking solder layer, and the melting temperature of the lacking solder layer is below that of the soldering tin preforms or soldering tin round blanks (1; 2).

10. The pre-tinning arrangement according to claim 9,
characterized in that
the soldering tin preforms consist of an alloy such as SAC305, Sn62Pb36Ag2 or Sn98Ag2 having melting points between 217° C. and 179° C., and the tacking solder consists of Sn42Bi47Ag1 by way of example, having a melting point of about 139° C.
